(19) United States
(12) Patent Application Publication
(10) Pub. No.: US 2015/0288322 A1
(43) Pub. Date: Oct. 8, 2015

(54) BUILDING ENVELOPE ELEMENT HAVING A FIRST GLASS LAYER AND A SECOND PHOTOVOLTAIC LAYER

(71) Applicant: ONYX SOLAR ENERGY, S.L., Avila (ES)

(72) Inventors: Alvaro Beltran Albarran, Avila (ES); Teodosio Del Cano Gonzalez, Avila (ES)

(21) Appl. No.: 14/436,649

(22) PCT Filed: Sep. 27, 2013
(86) PCT No.: PCT/ES2013/070671

§ 371 Date: Apr. 17, 2015

(30) Foreign Application Priority Data
Oct. 22, 2012 (ES) P201231628

(51) Int. Cl. H02S 20/26; H02S 40/34; H01L 31/048; E04F 13/08; E06B 7/28

(52) U.S. Cl. CPC H02S 20/26; E04F 13/0866; E06B 7/28; H01L 31/0488; H02S 40/34

(57) ABSTRACT

Building envelope element formed by: a first layer (1) of glass; a second photovoltaic layer (2); a third layer (3) of encapsulation and fourth layer (4) of glass.

### FIELD OF THE INVENTION

The present invention is included within the field of building envelope elements for construction.

### BACKGROUND OF THE INVENTION

Currently the laminated glass composed of one or more monolithic glass units is a common component in building areas where is interesting to have a transparent material allowing to observe other areas, or permitting the natural light to pass inside the building. This frequent use is due to the fact that laminated glass is considered as a safety glass because the capacity of the encapsulation to maintain the pieces of glass adhered in case of breakage.

Composites based on PVB (polyvinyl butyral) are the more usual encapsulation used to form the laminated glass due to its mechanical and transparent properties, being also possible the use of EVA (Ethylene-vinyl acetate) or other polymeric composites with similar characteristics [US2011315216]. All of these encapsulations can be prepared, by the incorporation of pigments, with the property of absorbing certain parts of the light spectrum, which results in a colored polymer. By incorporating pigmented encapsulation as part of the laminated glass, the final unit of glass consists of a transparent element with specific features of radiative transmittance obtained from the pigment incorporated into the encapsulation.

As the pigments, and therefore the optical characteristics, are limited, different encapsulations can be combined in one unit of laminated glass with the intention of achieving a particular and accurate filtering,

The trend in the design of the building facades, where the aim is to achieve the greatest possible transparency degree, highlights the importance of aspects related to the thermal performance and the sun protection of the building.

The concept of solar protection involves minimizing the access of solar energy into the building, with the intention of controlling the excessive heating due to solar gain.

Moreover, the thermal efficiency refers to the reduction of heat loss through the walls, from the inside to the outside of the envelope, improving the energy balance of the building. Solar radiation control through the glass means to prevent that part of the solar radiation incidence on the glass to pass into the interior of the building. Choosing a solar control system is always a compromise between a minimum energy gain and the maximum use of natural light in the building.

Furthermore, currently the different photovoltaic technologies are being result of several changes with the intention of being incorporated in buildings (Building Integrated Photovoltaics, BIPV) as electric power generators.

The combination of photovoltaic technology with different transmittance strategies or solar selective reflectance is a subject approached from different points of view given its interest in the BIPV sector:

1. Transparent amorphous silicon+tinted glass

2. Other cases

1. Transparent amorphous silicon+tinted glass

In this sense, some experiments with a combination of transparent amorphous silicon technology and tinted glass have been tested, showing many problems when its architectural implementation is carried out:
A drawback of the tinted glass is that it requires higher cost and very specialized equipment, since the pigmentation of the metal oxide is introduced at the stage of molten the glass, so the number of industries that can perform this technique is limited. This fact involves the necessity of manufacturing large quantities to produce in a competitive manner and long delivery times.
Moreover the available options in terms of dimensions and thickness of the final glass are greatly reduced due to the complexities of the manufacturing techniques, since these parameters are generally determined by the pigment added. In practice, this greatly limits the possibilities of the construction elements that incorporate it.
Also, this type of glass is not suitable for tempering process due to incompatibilities between the high temperatures needed and the characteristics of nucleation of the metal oxides incorporated for the pigmentation. This prevents their use in applications involving bending stresses, or when a secure glass breakage is needed. From the architectural point of view, where all these qualities are often mandatory, its application is very limited.
Filtering options are limited to a few available pigments, making it impossible combining them to adapt and customize the final optical result. This fact shows limitations in the customization properties of light transmittance, color, solar control and solar gain.

All these features greatly limit the possible applications of the proposed system based on the use of tinted glass with transparent photovoltaic technology for its architectural implementation and its optimized configuration to ensure inner comfort. [Transparent amorphous silicon PV-Facade as part of an integrated concept for the energetic rehabilitation of an office building in Barcelona. EUPVSEC 2005]

2. Other cases

Apart from the traditional blue color of polycrystalline or monocrystalline silicon cells, another different colors have been obtained by changing the deposition of the anti-reflective coating (ARC) incorporated, it can be also adapted to achieve reflection of certain wavelengths depending on its thickness. This gives the cells a colored appearance, however it loses efficiency depending on the color you want to obtain. Moreover, the results are opaque cells not allowing the passage of natural light.

Additionally, another option for combining the photovoltaic effect and colored glass is the use of amorphous silicon layers with less thickness, which in combination with transparent electrical contacts results in a certain degree of transparency linked to the light absorption limitations of the silicon. Colors achieved with this technology are only related to a chromatic hue (gold, red and brown) and linked to a degree of transparency, consequently the color determines the transparency and efficiency of the device.

In addition, the possibilities of incorporating different selective filters between the first monolithic glass and the amorphous silicon film based on antireflection coatings have been studied, with the intention of colouring the opaque photovoltaic glasses. These treatments are located in front of the active layer, which therefore produce losses in the electricity generation efficiency of the photovoltaic layer depending on the colour. On the other hand, its implementation has been made without the addition of any degree of transparency. [Efficiency of silicon thin-film photovoltaic modules with a front coloured glass]

There are also patents that include the combination of colors with amorphous silicon photovoltaic technology but based on the incorporation of pigments on layers of polyethylene terephthalate (PET) US2011315216.

### DESCRIPTION OF THE INVENTION

The invention is referred to a budding envelope element according to claim 1. The preferred embodiments of the element are defined in the dependent claims.

The invention includes incorporating a layer based on thin film of photovoltaic technology in an inner region of the laminated glass with a selective encapsulation, where the photovoltaic layer also has the property of being transparent. Thereby, it is obtained a laminated glass with color that in addition produces electric energy, filtering out much of the external radiation and regulating the heat when it goes through the glass.

This incorporation allows to obtain other advantages such as controlling the optical parameters or decreasing the ultraviolet radiation. From the last effect mentioned it follows that the transparent photovoltaic configuration helps to slow down the degradation of some pigments incorporated in the encapsulation, so this problem is reduced in this type of encapsulations. On the other hand, a new challenge arises i.e. to decrease the high heating of the encapsulation due to the absorption of radiation by the photovoltaic layer.

In the context described above, where the choice of a solar control system is always a compromise between the minimum gain of energy in the building and the maximum use of natural light, the use of selective glasses implies an advantage over the traditional building solutions of solar control (sunshades, slats, etc.). Selective glazing means the ability to filter certain wavelengths of incident radiation, either by reflection or absorption.

The capacity of controlling the solar radiation and the heat gains by using selective encapsulation results in controlling the following properties:
Transmission of visible light
Reflection of visible light
Solar Transmittance
Absorption of solar energy
Solar Heat Gain Coefficient (SHGC)

As shown above, the versatility of this type of solution to establish a hygrothermal building control is extensive.

In addition it is necessary to consider other factors that added to the previous properties provide this solution with a tremendous versatility:
Security: To protect the occupants of the buildings and pedestrians from accidental impacts, broken parts or precipitation of glasses. Security against the entrance of thieves and forced entry, security against impacts,
Acoustics: To reduce the outdoor sound transmission into buildings.
Storms/Hurricanes: Possible configurations for laminating glass for protection of strong winds.

In addition, the trend in the construction is to incorporate to the glass solar control properties. Often, what was established as a way to provide natural light is becoming, for architects, a tool of control of internal comfort conditions.

The possibility of controlling the optical properties of the glazing by combining encapsulation techniques with different pigments greatly extends the capabilities of adapting the glass for every architectural requirement in terms of the properties required in each building.

Despite the wide range of solutions offered, the possibilities in terms of optical control and constructive adaptability are limited, due to the use of tints in the proper glazing. Thanks to the combination of different layers—each of them with a pigment—two thousand different results can be achieved helping to create the most suitable optical characteristics.

### BRIEF DESCRIPTION OF THE DRAWINGS

A brief description with several drawings to understand better the invention is shown in FIGS. 1-4. All these drawings are expressly related to an embodiment of the invention presented as a non-limiting example thereof.

FIG. 1 shows a schematic section according to a first embodiment of the invention.

FIG. 2 shows a schematic section according to a second embodiment of the invention.

FIG. 3 shows a perspective diagram according to a first embodiment of the invention.

FIG. 4 shows a perspective diagram according to a second embodiment of the invention.

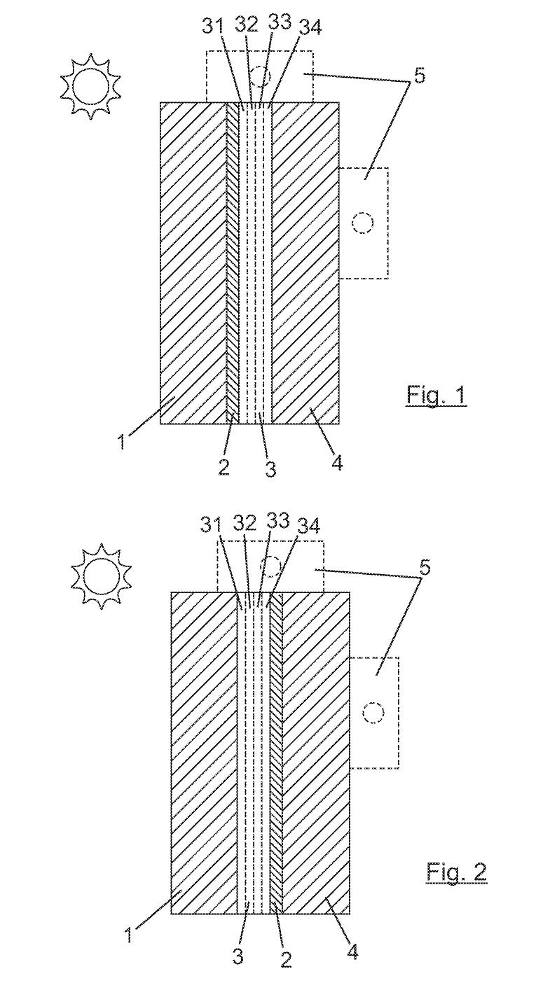

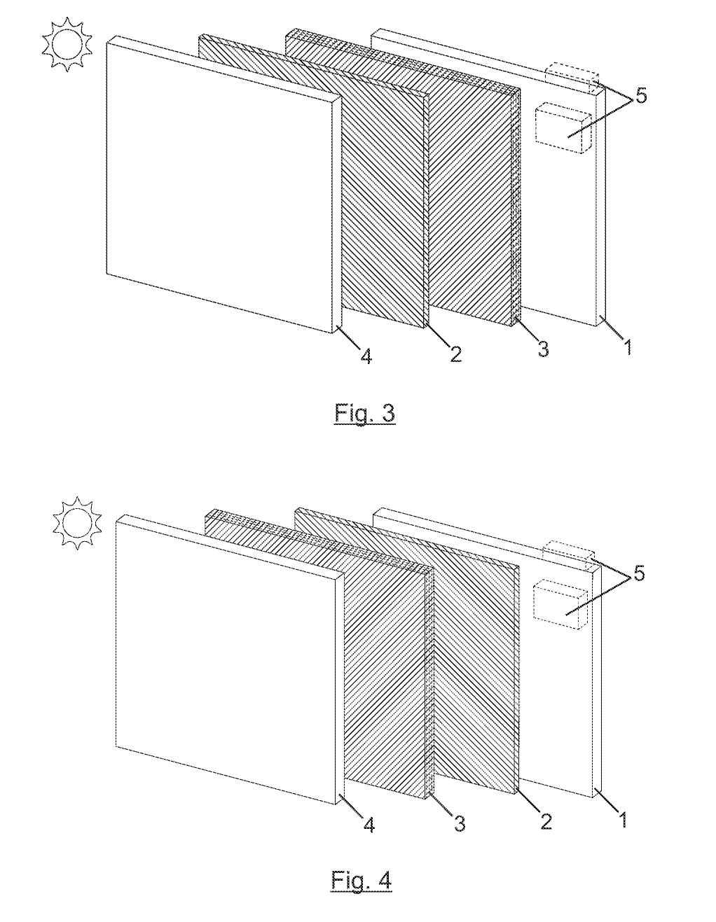

### DETAILED DESCRIPTION OF THE INVENTION

One embodiment of the invention refers to a building envelope element having a first layer (1) of glass and a second photovoltaic layer (2) comprising:

1c) a third layer (3) of encapsulation;

1d) a fourth layer (4) of glass.

The first layer (1) of glass and the fourth layer (4) of glass contain both the second photovoltaic layer (2) and the third layer (3) of encapsulation.

According to other characteristics of the invention:

2. The second layer (2) is transparent.

3. The second layer (2) is a thin film photovoltaic layer.

4. The third layer (3) includes a plurality of pigmented encapsulations configured to allow the passage of electromagnetic radiation within a certain range. In other words, the third layer (3) allows filtering electromagnetic radiation comprised in a certain range, either by reflection or absorption.

5. The third layer (3) is a pigmented polymeric encapsulation, typically PVB or EVA.

6. The second layer (2) is selected between amorphous silicon (a-SO, CdTe (cadmium telluride) and CICS/CIS.

7. The third layer (3) includes several films (31, 32, 33, 34).

8. The second layer (2) and the third layer (3) are disposed with respect to the electromagnetic radiation source in one of the following orders:

8a) second layer (2) and third layer (3);

8b) third layer (3) and second layer (2).

To be exact, the third layer (3) of encapsulation may be ahead or behind the second photovoltaic layer (2).

9. The building envelope element comprises a fifth glass layer sandwiched between the second layer (2) and the third layer (3).

10. The budding envelope element comprises: a junction box (5) for transporting the electrical energy generated in the second layer (2).The junction box (5) can be placed either on a selected location in the part behind all layers (1, 2, 3, 4) or at the edge of the building envelope element.

The preferred configuration corresponds to the second layer or photovoltaic active layer (2) ahead of the third layer (3) or encapsulation set, which provide glass the color properties; with this configuration, power production losses resulting from the absorption of a part of the spectrum by the third layer (3) or encapsulation, are avoided.

Typically, this active layer is based on thin film photovoltaic technology based on amorphous silicon (a-Si). In this case, the second layer (2) begins by a nanometer application of a transparent conductive material (typically, ITO or AZO); it continues with the application of the n-i-p layer of amorphous silicon to end with the application of a back contact metal (typically Al or Ag). All these depositions are made using thin film creation techniques such as sputtering or PECVD.

Subsequently, by laser processing, the opaque materials in small areas that are repeated throughout the glass to allow the passage of light, are removed. The removed area determines the degree of transparency of the active photovoltaic layer. Although laser technology allows to remove large areas, typically those areas of removed active material have a thickness on the order of microns, so that the distance between them is sufficiently small for an homogeneous light passage. This will have a direct effect on the internal lighting comfort when these elements are used as building envelope elements. [More information: WO2010089364 or WO2010123196].

Also, there is another possibility when the transparency is achieved, not by removing part of the active material through laser process, but because the application of absorbent material (in this case a-Si), is less thick than usual in combination with two transparent contacts. This way of achieving transparency in the photovoltaic layer is analogous to the one described in the second paragraph of section 2 (Other cases).

The possibility of the application of the active layer after the third layer (3) or encapsulation is also contemplated, being this layer also composed of thin film photovoltaic technology as CIS/CIGS or based on analogous compounds from the point of view of the electronic structure.

The creation of the photovoltaic layer with this technology would begin by the deposition of the back contact (typically molybdenum), then the layer of CulnₓGa₍₁₋ₓ₎Se₂ (with 0<x<1) is deposited to finish with a transparent contact. In this case the characteristics of the deposition order determine the position of the active layer with respect to the encapsulations.

Once the second layer (2) or photovoltaic active layer has been incorporated over one of the inner faces of the monolithic glass units, the union of the set is produced by a specific lamination process for these type of solutions. This specific process consists of the incorporation of both the active layer and the selective pigmentation in the third layer (3) or encapsulation.

The process continues with the positioning of the encapsulation between the two monolithic units, where they have to be placed appropriately to ensure the optimal optical properties. Then a certain pressure and temperature is applied on the glass sides, so that, following each magnitude some curves of a specific behavior, the polymer exceeds its glass transition point and adheres both to untreated glass and to the inner side which contains the photovoltaic technology; this difficulty has been already described in the state of the technique, for example in US2011315216 paragraph [0011]. After this process, the set is assembled, only in absence of removing the excess of encapsulation material on the edges.

The choice of the glass features will change depending on the requirements, being common the use of extra-clear glass for the piece exposed to the radiation. Regarding the structural features, the use of tempered glass is recommended or required for various applications.

This element, once laminated, is capable of being used as a replacement for any other type of laminated glass.

The parameters of the process (pressure, temperature and time) determine the interpenetration of some films with others where the pigment mixture can vary the optical properties of the set, as well as certain essential mechanical properties for architectural applications and specific applications of the security glass.

Also, the difficulty of sealing correctly the edges of the laminated unit is increased when using multiple films of encapsulation, due to an increment in the probability of generating weak junction areas both between the films and between the films and the glasses. Finally, some conductive elements placed as contacts on the photovoltaic inner zone are responsible for conducting the electricity to an external connection box. The configuration of these connections can vary depending on the electrical configuration of the photovoltaic layer.

Apart from the common difficulties during the manufacturing stage when both technologies are joined, there are other particular issues that need to be considered during the operation stage.

On one hand, the possibility of moisture penetration into the laminated unit is especially critical due to the fact that a part of the electrical elements are contained there such as the photovoltaic elements. This is especially complex in multilayer configurations due to its influence on the creation of moisture diffusion cores.

Furthermore, radiative absorption characteristics of the photovoltaic layers within much of the solar spectrum produce a temperature increase of the glass inner zone which can reach up to 70° C. for a high number of hours per year. This requires previous optimization based on the pigments incorporated in the encapsulation, and some studies and considerations regarding both location and orientation matters, to guarantee an optimal durability of the system.

1. Building envelope element having a first layer of glass and a second photovoltaic layer comprising:
1c) a third layer (3) of encapsulation;
1d) a fourth layer (1) of glass.

2. Building envelope element having a first layer of glass and a second photovoltaic layer according to claim 1 characterized by the transparency of the second layer.

3. Building envelope element having a first layer of glass and a second photovoltaic layer according to claim 1, wherein the second layer is thin film.

4. Building envelope element having a first layer of glass and a second photovoltaic layer according to claim 1, wherein the third layer comprises a plurality of pigmented encapsulation films configured to allow the passage of electromagnetic radiation within a certain range.

5. Building envelope element having a first layer of glass and a second photovoltaic layer according to claim 1, wherein the third layer is a pigmented polymeric encapsulation.

6. Building envelope element having a first layer of glass and a second photovoltaic layer according to claim 1, wherein the second layer is selected between amorphous silicon (a-Si), cadmium telluride (CdTe) and CIGS/CIS.

7. Building envelope element having a first layer of glass and a second photovoltaic layer according to claim 1, wherein the third layer comprises a plurality of films.

8. Building envelope element having a first layer of glass and a second photovoltaic layer according to claim 1, wherein the second layer and the third layer are disposed with respect to the electromagnetic radiation source in one of the following orders:
8a) second layer and third layer;
8b) third layer and second layer.

9. Building envelope element having a first layer of glass and a second photovoltaic layer according to claim 1, comprising a fifth layer of glass sandwiched between the second layer and the third layer.

10. Building envelope element having a first layer of glass and a second photovoltaic layer according to claim 1, comprising a junction box for transporting an electrical energy generated in the second layer.
